(19) United States
(12) Patent Application Publication
(10) Pub. No.: US 2013/0240196 A1
(43) Pub. Date: Sep. 19, 2013

(54) CONTAINER WITH COOLING SYSTEM

(71) Applicant: YAO-TING CHANG, Tu-Cheng (TW)

(72) Inventor: YAO-TING CHANG, Tu-Cheng (TW)

(73) Assignee: HON HAI PRECISION INDUSTRY CO., LTD., Tu-Cheng (TW)

(21) Appl. No.: 13/457,713

(22) Filed: Apr. 27, 2012

(30) Foreign Application Priority Data
Mar. 16, 2012 (TW) 101109163

(51) Int. Cl. H05K 5/00; H05K 7/20; G05D 23/19

(52) U.S. Cl. 165/247; 165/80.3

(57) ABSTRACT

A container includes a main body, a number of computer servers, a number of heat dissipating fins, a first group of fans and a second group of fans. Two frames are symmetrically mounted in the main body. The frames divide the main body to a middle airflow channel and side airflow channels. The computer servers are positioned in the frames. The heat dissipating fins are positioned on the main body. A number of flow spaces are defined between the heat dissipating fins. A first group of fans are positioned in the middle airflow channel, and a second group of fans are positioned in the side airflow channels. The first group of fans draws the airflow into the middle airflow channel to pass through the computer servers, and the second group of fans draws the airflow passing through the computer servers to the heat dissipating fins.

### BACKGROUND

1. Technical Field

The disclosure generally relates to cooling systems, particularly to a container including a cooling system which uses outside air to dissipate heat generated by computer servers in the container.

2. Description of Related Art

To quickly establish a cloud operating system, a container is typically used to act as a room for the cloud operating system. When designing a container for containing multiple computer servers, an air conditioner is installed in the container for controlling the temperature to a desirable level to cool the computer servers.

However, air conditioners usually consume high amounts of power. When outside temperatures become lower, for example, in winter, the container cannot use outside temperatures efficiently to cool the computer servers, wasting power.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary container with cooling system. Moreover, in the drawings, like reference numerals designate corresponding parts throughout the several views. Wherever possible, the same reference numbers are used throughout the drawings to refer to the same or like elements of an embodiment.

FIG. 1 is a schematic view of an embodiment of a container including a cooling system.

FIG. 2 is a schematic view in the container in FIG. 1 showing a flowing routine of hot and cold airflow.

FIG. 3 is a block diagram depicting the control system for controlling the container with cooling system.

### DETAILED DESCRIPTION

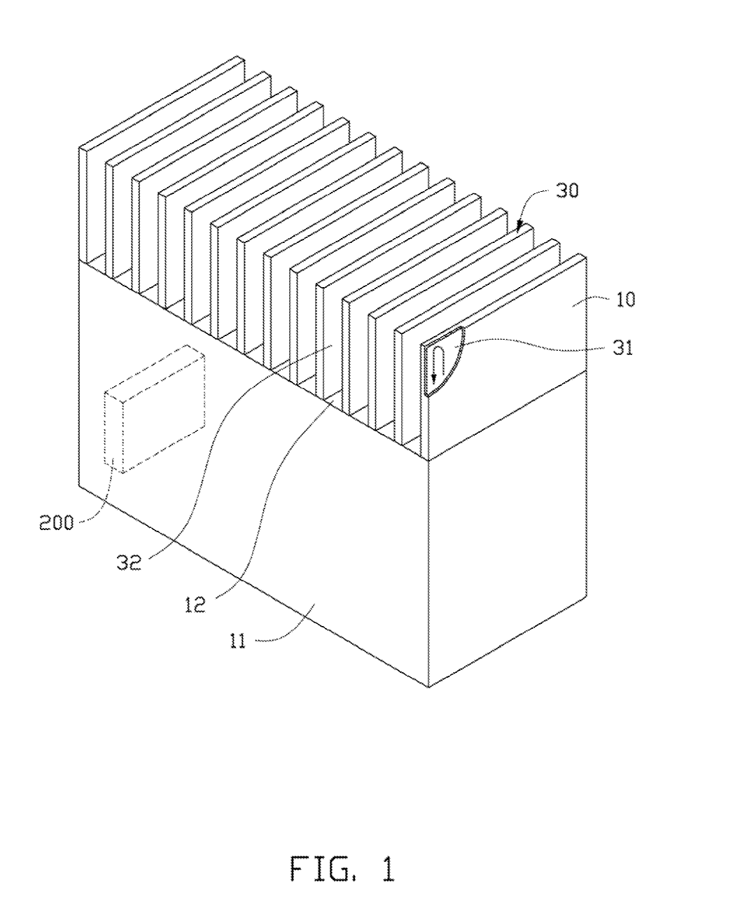

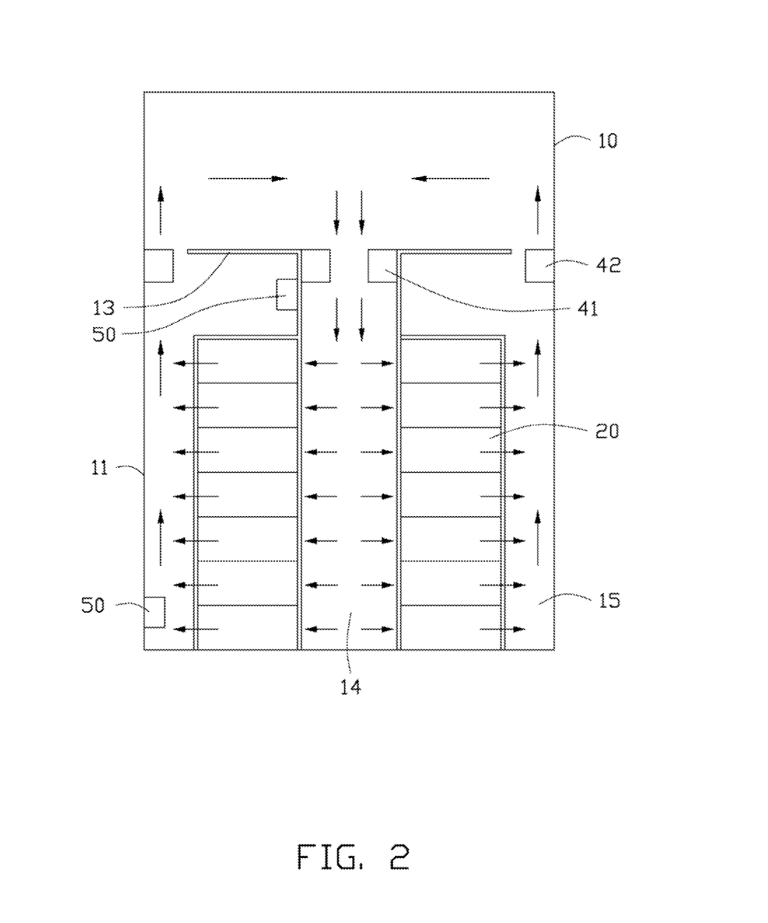

FIGS. 1 and 2, show an exemplary container 10 used for housing electrical equipment, such as telecommunication components. In this exemplary embodiment, the container 10 includes a number of computer servers 20, a number of heat dissipating fins 30, a first group of fans 41, and a second group of fans 42.

The container 10 includes a hollow main body 11 with a top wall 12. Two frames 13 are symmetrically mounted in the main body 11. The computer servers 20 are arranged in the frames 13. The frames 13 divide the main body 11 to create a middle airflow channel 14 and two side airflow channels 15. Each computer server has conventional air vents (Not shown) that allow air to be drawn into and exit the computer server. Cold air from the middle airflow channel 14 allows cold airflow to be drawn into and pass through the computer server. Warm air is drawn into and passes through the computer server and exit through side airflow channels 15 to allow hot airflow to pass through. An air condition 200 is installed in the main body 11 for controlling the temperature to a desirable level to cool the computer servers 20. One or more sensors 50 are mounted in the container 10 for detecting an inside temperature of the container 10.

The heat dissipating fins 30 are positioned parallel to each other and positioned along the top wall 12. Each heat dissipating fin 30 includes a hollow cavity 31, and communicates with an inside of the main body 11. A number of flow spaces 32 are defined between the heat dissipating fins 30. Cold airflows passing through the flow spaces 32 can cool the hot airflow in the cavity 31. To have a high heat dissipating effect, each heat dissipating fin 30 is made of metal.

The first group of fans 41 is positioned in the middle airflow channel 14, and the second group of fans 42 is positioned in the side airflow channels 15. The first group of fans 41 directs a cold airflow to the middle airflow channel 14 for heat dissipating heat from the computer servers 20. The second group of fans 42 directs hot airflow through the side airflow channels 15 to the heat dissipating fins 30.

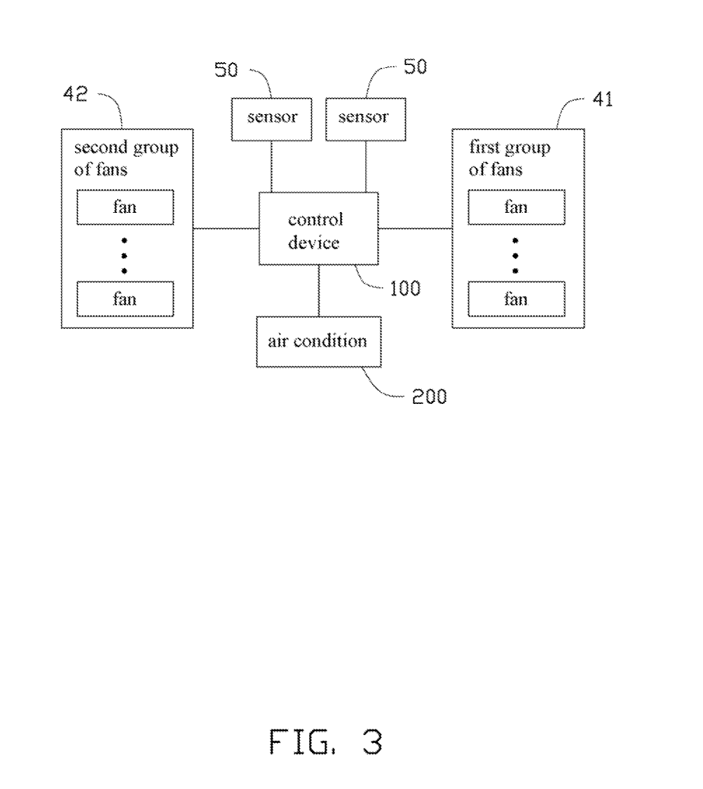

FIG. 3 is a block diagram depicting the control system for controlling the container with cooling system. A control device 100 is electronically connected to the first and second group of fans 41, 42, and the air conditioner 200. The control device 100 can receive an inside temperature of the container 10 detected by one or more sensors 50. The controller device 100 compares the detected temperature with a predetermined temperature, for example, 25° C. If the inside temperature of the container 10 is determined to be lower than the predetermined temperature, the control device 100 transmits a signal to turn off the air conditioner 200, and activates the first, second group of fans 41, 42 for heat dissipating heat.

FIG. 2 is used for showing a state in use. When the controller device 100 causes the first group of fans 41 and the second group of fans 42 to operate, the first group of fans 41 draws cold airflow to the middle airflow channel 14 for heat dissipating heat of the computer servers 20. The second group of fans 42 draws hot airflow in the side airflow channels 15 to the heat dissipating fins 30. The hot airflow in the heat dissipating fins 30 are cooled by the cold air in the flow spaces 32 to be further directed to the middle airflow channel 14. Accordingly, the container 10 uses the outside airflow to dissipate heat.

It is to be understood, however, that even through numerous characteristics and advantages of the disclosure have been set forth in the foregoing description, together with details of the system and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A container comprising:
a main body, two frames symmetrically mounted inside the main body, the frames dividing the main body to a create middle airflow channel and side airflow channels;
a plurality of computer servers positioned in the frames;
a plurality of heat dissipating fins positioned on the main body, a plurality of flow spaces defined between the heat dissipating fins;
a first group of fans positioned in the middle airflow channel, and a second group of fans positioned in the side airflow channels;
wherein airflow in the main body is cooled by air in the flow space between the heat dissipating fins, the first group of fans draws the airflow into the middle airflow channel to pass through the computer servers, the second group of fans draws the airflow passing through the computer servers to the heat dissipating fins.

2. The container as claimed in claim 1, wherein the main body includes a top wall, and the heat dissipating fins are parallel to each other and positioned along the top wall.

3. The container as claimed in claim 2, wherein each heat dissipating fin is made of metal.

4. The container as claimed in claim 2, wherein each heat dissipating fin including a hollow cavity, and the hollow cavity communicates with the main body.

5. A container comprising:
a main body defining a create middle airflow channel and side airflow channels;
a plurality of computer servers positioned in the main body;
a plurality of heat dissipating fins positioned on the main body, a plurality of flow spaces defined between the heat dissipating fins;
a first group of fans positioned in the middle airflow channel, and a second group of fans positioned in the side airflow channels; and
a control device electronically connected to the first group of fans and the second group of fans;
wherein the control device activate the first group of fans and the second group of fans, airflow in the main body is cooled by air in the flow space between the heat dissipating fins, the first group of fans draws the airflow into the middle airflow channel to pass through the computer servers, the second group of fans draws the airflow passing through the computer servers to the heat dissipating fins.

6. The container as claimed in claim 5, further comprising an air condition, wherein the control device is electronically connected to the air conditioner, the control device transmits a signal to turn off the air conditioner when the control device detects an inside temperature of the container lower than a predetermined temperature.

7. The container as claimed in claim 6, further comprising at least one sensor, wherein the at least one sensor is electronically connected to the control device and detects the inside temperature of the container.

8. The container as claimed in claim 5, wherein the main body includes a top wall, and the heat dissipating fins are parallel to each other and positioned along the top wall.

9. The container as claimed in claim 8, wherein each heat dissipating fin including a hollow cavity, and the hollow cavity communicates with the main body.
